(19) United States
(12) Patent Application Publication
(10) Pub. No.: US 2026/0340235 A1
(43) Pub. Date: Oct. 29, 2026

(54) SYSTEM AND METHOD FOR MEDICAL/SURGICAL TRAINING USING BIOPOLYMERIC COMPOSITE GELS, RAPID PROTOTYPING, AUGMENTED REALITY, AND ARTIFICIAL INTELLIGENCE

(71) Applicants: Lindsey G. Zeichner, New York, NY (US); Samuel J. Zeichner, Fort Lauderdale, FL (US)

(72) Inventors: Lindsey G. Zeichner, New York, NY (US); Samuel J. Zeichner, Fort Lauderdale, FL (US)

(21) Appl. No.: 19/662,525

(22) Filed: Apr. 29, 2026

Related U.S. Application Data
(60) Provisional application No. 63/796,376, filed on Apr. 29, 2025.

(51) Int. Cl. G06F 30/27

(52) U.S. Cl. CPC G06F 30/27

(57) ABSTRACT

A medical/surgical training system is disclosed for providing both anatomically representative and haptically realistic simulation of medical procedures. The system includes anatomically representative data used to generate a digital anatomically representative model and a physical simulation model. The physical simulation model includes a biological tissue component comprising a biopolymeric composite gel configured to emulate mechanical properties of human soft tissue. A rapid prototyping subsystem fabricates a portion of the physical simulation model from the anatomically representative data. An augmented reality (AR) subsystem presents instructional content spatially aligned with the physical simulation model, while an artificial intelligence (AI) subsystem monitors user interaction and provides procedural feedback based on stored procedural criteria. The system supports procedural training, simulation, rehearsal, and performance evaluation in medical and surgical applications.

### CROSS-REFERENCE TO RELATED APPLICATIONS

This application claims priority to U.S. Provisional Patent Application No. 63/796,376, titled “A System and Method for Medical/Surgical Training Using Biopolymeric Composite Gels, Rapid Prototyping, Augmented Reality, and Artificial Intelligence,” filed on Apr. 29, 2025, the contents of which are hereby incorporated by reference in their entirety.

### FIELD OF THE INVENTION

The present disclosure relates generally to medical and surgical training systems and, more particularly, to system and method for medical/surgical training using biopolymeric composite gels, rapid prototyping, augmented reality, and artificial intelligence.

### BACKGROUND OF THE INVENTION

Generally, a significant challenge in medical education lies in the effective training of medical and surgical residents along with auxiliary healthcare personnel to perform delicate and complex procedures. The traditional Halstedian method, which involves learning through direct practice on living patients, is increasingly considered unacceptable owing to ethical concerns and issues pertaining to patient safety. Cadaver-based training, while historically valuable, is not readily accessible due to high costs, logistical constraints, and regulatory requirements. Furthermore, cadaveric tissues often fail to replicate realistic biomechanical and haptic properties because of post-mortem degradation. Animal models, once widely used, have been largely phased out due to ethical concerns and anatomical dissimilarities with human tissues, limiting their relevance for human-specific procedures.

Existing synthetic and virtual reality (VR) training models also have present significant limitations. Synthetic soft-tissue analogues, commonly composed of silicone-based materials, do not accurately replicate the complex biomechanical properties of human soft tissue. VR simulation systems, while interactive, lack adequate haptic feedback, which is critical for developing procedural and tactile proficiency. Additionally, such systems are often expensive and technologically intensive, limiting their accessibility and scalability. Another key limitation of existing training modalities is the lack of patient-specific modelling. Current systems do not enable surgeons to rehearse procedures tailored to an individual patient's anatomy, thereby restricting opportunities for preoperative planning and risk mitigation.

Accordingly, there exists a need for an improved medical/surgical training system that overcomes the aforementioned limitations.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

The present invention addresses these challenges by integrating biopolymeric composite gels (BCGs) with patient-specific rapid prototyping techniques to produce simulation models configured to provide anatomically representative geometry and haptically realistic tissue interaction during manipulation.

The disclosed systems and methods enable improved spatial anatomical simulation and enhanced tactile feedback and user interaction response, thereby supporting more effective training and preoperative rehearsal in a cost-efficient manner.

A medical/surgical training system is disclosed that enables both anatomically representative and haptically realistic simulation of procedures. The system comprises an anatomically representative physical model (or biological tissue component) integrated with a physical simulation model formed in part from a biopolymeric composite gel (BCG) configured to emulate the mechanical properties of human tissue. The physical simulation model is partially fabricated using a rapid prototyping subsystem based on digital anatomical data of the biological tissue component, enabling patient-specific customization.

An augmented reality (AR) subsystem is provided to overlay instructional content onto the physical simulation model, including visual cues, annotations, and step-by-step procedural guidance aligned with anatomical structures.

An artificial intelligence (AI) subsystem is configured to track user interaction, analyze procedural performance, and provide real-time or delayed feedback, including performance scoring and guidance.

The disclosed system overcomes limitations of existing training modalities by combining haptically accurate tissue simulation, spatial anatomical accuracy, and interactive digital guidance. The invention facilitates skill acquisition across a range of medical disciplines and enables scalable, cost-effective, and optionally instructor-independent training in both resource-rich and low-resource environments.

Advantageously, the present invention provides several significant advantages over existing medical and surgical training systems. The present technology uses biopolymeric composite gels (BCGs) which enable accurate replication of the mechanical and tactile properties of human soft tissues, improving procedural realism compared to conventional synthetic materials. An integration with rapid prototyping technologies allows fabrication of anatomically precise models, closely replicating real human structures and in situ spatial relationships. The system can be generated from patient-specific digital anatomical data, enabling preoperative rehearsal and personalized procedural planning, thereby reducing intraoperative risk. The combination of physical simulation, augmented reality guidance, and artificial intelligence-driven feedback accelerates learning and improves procedural competency. The present technology eliminates the need for live patient training, reduces reliance on cadavers and animal models, and addresses ethical concerns associated with traditional training methods. The present technology offers a more affordable and scalable solution suitable for widespread adoption, including in low-resource settings, compared to cadaveric and high-end virtual reality systems. The AI subsystem provides objective performance evaluation, including motion tracking, scoring, and corrective guidance, enabling continuous improvement without constant expert supervision. The augmented reality subsystem enhances user engagement by overlaying real-time instructional content directly onto the physical model. The system can be adapted for various applications, including surgical, dental, anesthesia, and diagnostic training. The present technology components can be reused or replaced independently, reducing long-term operational costs and allowing flexible training configurations. The system supports remote expert interaction and asynchronous learning, enabling training across geographically distributed users. The properties of the BCG can be adjusted to simulate different tissue types such as skin, muscle, fat, and connective tissue, increasing the breadth of training scenarios. Additionally, unlike silicone, a polymer comprised of siloxane, the glutenin/gliadin gel uses a biopolymer of two plant polypeptides, the resultant polymer more closely resembles the structure of skeletal muscle and concomitantly more accurately mimics the haptics of soft tissue during medical procedures. Similarly, collagen-derived hydrogels formed from animal-derived polypeptides, may expand the haptic characteristics suitable for simulating additional tissue categories, including adipose tissue, fascia, glandular tissue, or connective tissue.

The primary objective of the present invention is to provide a medical/surgical training system that enables realistic simulation of medical procedures with both anatomical accuracy and haptic fidelity.

Another objective of the invention is to provide a soft-tissue simulation component comprising a biopolymeric composite gel capable of mimicking the mechanical and haptic properties of human tissue.

A further objective of the invention is to enable the fabrication of anatomically representative physical models using rapid prototyping techniques based on digital anatomical data.

Another objective of the invention is to facilitate patient-specific simulation models to allow preoperative rehearsal and procedural planning.

A further objective of the invention is to integrate an augmented reality (AR) subsystem for overlaying instructional content, including visual cues, annotations, and step-by-step procedural guidance, onto the physical model.

Another objective of the invention is to incorporate an artificial intelligence (AI) subsystem configured to track user interaction, evaluate procedural performance, and provide real-time or delayed feedback.

A further objective of the invention is to improve skill acquisition and procedural competency through a combination of physical simulation and digital guidance.

Another objective of the invention is to provide a training system that reduces reliance on cadavers, animal models, and live patient training, thereby addressing ethical and logistical concerns.

A further objective of the invention is to provide a cost-effective and scalable training solution suitable for use in both resource-rich and low-resource environments.

Another objective of the invention is to enable asynchronous and remote training, including the ability for expert interaction and performance assessment.

A further objective of the invention is to provide a versatile training platform adaptable to multiple medical disciplines, including surgical, dental, anesthesia, and diagnostic procedures.

Another objective of the invention is to provide a system with tunable soft-tissue properties to simulate different types of human tissues.

### BRIEF DESCRIPTION OF FIGURES

The invention is illustrated in the accompanying drawings, in which like reference numerals designate corresponding parts throughout the various figures. The embodiments described herein, along with their advantages, will be better understood when considered in conjunction with the drawings, wherein:

FIG. 1 illustrates a block diagram of a medical or surgical training system, in accordance with an embodiment.

FIG. 2A illustrates a process flowchart of AR/AI creation of instructional content for simulation training, in accordance with an embodiment.

FIG. 2B illustrates a process of fabrication of physical/anatomic replica(s) for simulation training, in accordance with an embodiment.

FIG. 2C illustrates a process of creation of instructional content for simulation training, in accordance with an embodiment.

FIG. 3A illustrates a scanning electron micrograph of gliadin/glutenin composite polymeric hydrogel in accordance with an embodiment.

FIG. 3B illustrates a scanning electron micrograph of actin/myosin/titin in a human muscle fiber, in accordance with an embodiment.

FIG. 4A illustrates a scanning electron micrograph of gliadin/glutenin composite polymeric hydrogel, in accordance with an embodiment.

FIG. 4B illustrates a scanning electron micrograph of collogen/glycerol composite polymeric hydrogel, in accordance with an embodiment.

FIG. 5 illustrates a preoperative simulation model of 19-week-old infant, in accordance with an embodiment.

FIG. 6A-6B illustrates a trainee participating in a self-directed simulation tutorial using AR/AI with navigation, annotation, animation, real-time guidance and feedback, in accordance with an embodiment.

FIG. 7 depicts a flowchart of a method for training a user in a medical or surgical procedure using a physical simulation model, in accordance with an embodiment.

FIG. 8 illustrates a flowchart of a method of producing a medical or surgical simulation model, in accordance with an embodiment.

FIG. 9 illustrates a flowchart of a method for patient-specific procedural rehearsal, in accordance with an embodiment.

FIG. 10 illustrates a block diagram of a computing device configured to perform any one or more of the methodologies herein, in accordance with an embodiment.

Further, it will be appreciated that elements in the figures are illustrated for simplicity and may not have been drawn to scale; various components may be represented by conventional symbols, and descriptions focus on pertinent details so as not to obscure the embodiments.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION OF THE DISCLOSURE

Some embodiments of the present disclosure, illustrating all its features, will now be discussed in detail. It must also be noted that as used herein and in the appended claims, the singular forms “a”, “an” and “the” include plural references unless the context clearly dictates otherwise.

Various modifications to the embodiment will be readily apparent to those skilled in the art and the generic principles herein may be applied to other embodiments. However, one of ordinary skill in the art will readily recognize that the present disclosure including the definitions listed here below are not intended to be limited to the embodiments illustrated but is to be accorded the widest scope consistent with the principles and features described herein.

A person of ordinary skill in the art will readily ascertain that the illustrated steps detailed in the figures and here below are set out to explain the exemplary embodiments shown, and it should be anticipated that ongoing technological development will change the way particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

As used herein, the terms “AI subsystem”, “AI system”, and “artificial intelligence system” are used interchangeably and refer to a computational system configured to evaluate user interaction and provide feedback. As used herein, the terms “physical model”, “physical simulation model”, “surgical simulation model,” “medical simulation model”, “operative field”, and “replica” are used interchangeably and refer to an anatomically representative structure configured for procedural simulation or training.

As used herein, the terms “biopolymeric composite gel (BCG)”, “biopolymeric composite hydrogel”, and “hydrogel” are used interchangeably and refer to a biopolymer-based material configured to simulate one or more mechanical properties of human tissue.

As used herein, the terms “instructional content”, “augmented reality instructional content”, and “training exercise” are used interchangeably and refer to digital guidance provided to a user during a medical or surgical procedure.

As used herein, the terms “digital anatomical model”, “digital twin”, and “three-dimensional model” are used interchangeably and refer to a digital representation of anatomical structures derived from imaging or computational data.

As used herein, ‘biomechanical properties’ refer to measurable physical characteristics of a material, while ‘haptic properties’ refer to how the material feels during touch, manipulation, cutting, or palpation.

As used herein, ‘rapid prototyping’ refers to techniques for rapidly fabricating physical structures from digital models. Rapid prototyping may include additive manufacturing processes, such as three-dimensional (3D) printing, as well as subtractive, molding, or hybrid fabrication methods.

As used herein, “spatially aligned” refers to positioning digital instructional content relative to a physical model such that the content corresponds to a location on, near, or surrounding the physical model. Spatial alignment may be determined based on proximity, orientation, distance, or relative position between the digital content and the physical model.

As used herein, ‘biological tissue component’ refers to a simulated tissue structure configured to replicate one or more anatomical, mechanical, or haptic characteristics of biological tissue.

As used herein, “anatomically representative data” refers to imaging data, scan-derived information, segmented anatomical datasets, or digitally reconstructed geometry corresponding to one or more anatomical structures. In certain embodiments, the anatomically representative data is stored in memory or a computing device and processed to generate a digital anatomically representative model used for fabrication, simulation, or procedural planning.

As used herein, user interaction data includes motion, tool position, timing, contact.

As used herein, “haptically realistic” refers to tactile characteristics perceived during user interaction with a simulation model, including feel, resistance, deformation, and motion response associated with manipulation of simulated tissue.

As used herein, “user” refers to an individual interacting with the surgical simulation model or associated system components. A user may include a surgeon, trainee, physician, medical student, instructor, technician, or other participant engaged in procedural training, simulation, rehearsal, or evaluation.

As used herein, “user interaction data” refers to procedural interaction information including motion trajectory, tool position, force application, timing, contact events, orientation, spatial positioning, and interaction relative to anatomical landmarks.

As used herein, the terms “medical/surgical simulation model,” “medical simulation model,” and “surgical simulation model” refer generally to anatomically representative simulation structures configured for procedural rehearsal, training, evaluation, or instruction. Although these terms may correspond to different procedural contexts, they may be used interchangeably throughout this disclosure unless a specific embodiment expressly requires a narrower interpretation.

As used herein, the terms “tissue-simulating model” and “physical simulation model” are used interchangeably and refer to a physical anatomically representative structure configured to replicate one or more anatomical tissues, tissue regions, or organ structures for procedural simulation, medical training, surgical rehearsal, evaluation, or instructional use.

In certain embodiments, references to gaming engines, gaming devices, augmented reality frameworks, or interactive development environments refer to software platforms used to generate instructional augmented reality content. Suitable platforms may include Unity-compatible tracking frameworks and software development kits (SDKs), including but not limited to Vuforia, ARToolKit, EasyAR Sense, Adobe Aero, or equivalent tracking environments.

In describing the invention, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

Various embodiments of the present technology use biopolymeric composite gels (BCGs) including two or more biopolymeric gelling components. The gelling components undergo chemical and physical changes that render the original liquid solution to a solid hydrogel by combining, hydrating, and mixing the gelling components under specific conditions. The mechanical properties of the hydrogel vary according to composition and curing conditions. Mechanical properties of the hydrogel may be estimated using material-mixture approximations including Young's modulus, shear modulus, and mixture-rule approaches such as Voigt approximations to guide formulation selection for target elasticity, stiffness, or rigidity. The present technology emulates the densities, elastic, and compressive properties of the cross-linked polypeptides by varying the formulations of composite gels. The resulting products have the haptics of human skin, muscle, fat, and loose areolar tissue. Moreover, because the biological materials are moldable, they can be used to precisely replicate the anatomy of a surgical field. Thus, with an inexpensive, precision medicine replica of a patient obtained from high resolution optical scanning or other complementary forms of digital imaging, a surgeon can preoperatively define and practice a surgical approach for a specific patient. BCGs are not only important for precision medicine applications but also, they are useful for training generic surgical or interventional procedures such as complex wound debridement and reconstruction in trauma or military medicine, fine needle aspiration of the thyroid, or percutaneous jugular sticks for CVC (central venous catheter) placement in the field of emergency medicine. The utility of surgical simulators has been hampered by the lack of anatomically and haptically accurate soft-tissue emulators. Generic surgical training on simulation models using remote expert feedback via the iPad/Android tablet navigation system opens the door to inexpensive, accessible global medical/surgical continuing medical education (CME) which is an innovative pathway to equalize healthcare distribution in developing nations where specialty medicine and surgery is lacking and solutions to enterprise level surgical training such as in military medicine.

The present technology has developed and investigated two distinct classes of biopolymeric composite hydrogels (BCGs) such as wheat-derived hydrogel and collagen-derived hydrogel as a soft-tissue simulation material. The first BCGs (wheat-derived hydrogel) is an inexpensive composite of two plant polypeptides comprised of glutenin and gliadin plus an admix of lipids. The composite biopolymer cools to form a gel having the mechanical properties of muscle after hydrated in appropriate proportions, molded, then warmed to a precalculated temperature. The superficial layer of the replica emulates the mechanical properties of skin and the deep layer replicates periosteum. The second BCG (collagen-derived hydrogel), evaluated as a soft-tissue emulator, is an inexpensive composite of an animal polypeptide (collogen-principal component of gelatin) plus glycerol (a polyalcohol that acts as a plasticizer) plus a polysaccharide (such as sucrose, mannose, or even food-grade honey). When hydrated in appropriate proportions mixed, heated, molded, then cooled to ambient temperature, the composite forms an anatomically and haptically accurate soft tissue replica with a range of soft-tissue properties depending upon the formulation parameters. All of the formulations investigated are inexpensive (<$1.00 US to mold a 75-cc model) and relatively quick to prepare a replica of the surgical field (30-45 minutes). BCGs are used extensively in the food industry, in the pharmaceutical and cosmetics industries, in tissue engineering, and even to make flesh-like special effects in the cinema. However, the use of BCGs for medical/surgical simulation training has not been documented in the existing literatures.

In an embodiment, admix of lipids includes fatty acids. The fatty acids are added to the glutenin/gliadin composite gel as part of the formulation anticipating that the addition of fatty acids might contribute to skin-like properties. The fatty acids includes linoleic acid, an essential fatty acid as an important component of cell membranes and the skin protective barrier, oleic acid, naturally present in the skin protective hydrolipidic film, palmitic acid and stearic acid are saturated fatty acids which contribute to the stability of the skin hydrolipidic film, and lecithin, which is a phosphorus-containing lipid with properties similar to fatty acids, contributing to skin hydration and strengthening the skin protective barrier. The proportions of fatty acids used in the mixture includes 50-60% of linoleic acid, 17-30% of oleic acid, 9-13% of palmitic acid, and 2.5-5.0% of steric acid. To achieve a fast, simple, inexpensive methodology, the fatty acid components are not synthesized, purified, and assayed. Instead, they are present in the right proportions in Wesson vegetable oil.

The first class of BCGs is derived from wheat proteins and is hereafter referred to as the glutenin/gliadin hydrogel. Glutenin and gliadin polypeptides can be isolated from wheat flour by repeated aqueous washing, during which the supernatant containing starch, fiber, and other soluble components is decanted until it becomes clear. The remaining insoluble fraction constitutes the glutenin/gliadin component of the gel. To simplify and standardize the glutenin/gliadin hydrogel preparation, a commercially available product (vital wheat gluten) is utilized, which contains approximately 80% protein composed primarily of glutenin and gliadin in an approximate 1:1 ratio, as specified by the manufacturer. In keeping with the theme of a fast, simple, inexpensive methodology, using commercially available product avoids the need for labor-intensive extraction while concomitantly maintaining consistent composition. The glutenin/gliadin hydrogel system comprises of four components including protein matrix, lipid phase, preservative and solvent. The protein matrix includes glutenin/gliadin, the lipid phase is a defined mixture of lipids, a preservative is either 0.1% antibacterial solution added to the aqueous phase, or 0.3% calcium propionate incorporated into the dry mixture and the solvent is distilled water (tap water is an acceptable substitute). The optional additives include food-grade dyes (added to the aqueous phase) or particulate pigments such as artist's flock (added to the dry phase) for coloration.

The second class of BCGs is based on collagen-derived gelatin. Upon hydrolysis, collagen degrades into shorter polypeptide chains such as a-chains (monomers), β-chains (dimers), and γ-chains (trimers), which are collectively referred to as gelatin. For molding applications, an unflavored gelatin, a 100% protein powder is used. The protein powder composed predominantly of α-chains, which facilitates efficient hydration (blooming). The collagen-derived gelatin hydrogel consists of four components, such as polymer matrix, primary plasticizer, secondary modifier, and solvent. The polymer matrix includes gelatin, the primary plasticizer includes glycerol, a sugar alcohol that increases flexibility by reducing intermolecular interactions between polymer chains, thereby enhancing elasticity but reducing mechanical strength, the secondary modifier includes sorbitol, which is incorporated alongside glycerol to improve structural integrity and counterbalance the loss of strength, and the solvent used is water. A preservative is not necessary for collagen-derived hydrogel preparation as the mixture is stable for 1 year when refrigerated in a sealed plastic bag. By varying the relative proportions of glycerol and sorbitol, the mechanical properties of the hydrogel can be tuned across a spectrum of stiffness and elasticity. This enables replication of a range of soft tissue characteristics, from relatively stiff structures (e.g., tendon) to compliant, highly deformable tissues (e.g., breast parenchyma or loose areolar tissue).

In certain embodiments, secondary modifiers including honey, sucrose, mannose, dextrose, saccharine, or related additives may alter tactile and surface properties of the hydrogel. Honey may improve elasticity moderation, but may impart coloration to the simulation model. Dextrose and saccharine may produce tacky surface characteristics that reduce suitability for procedural simulation.

Glutenin/gliadin hydrogel system is used primarily to replicate the haptic properties of skin, skeletal muscle, and periosteum. A single formulation is employed across these tissue types. Differences in mechanical behavior arise not from compositional changes, but from curing conditions specifically, temperature gradients associated with proximity to the mold surface. Regions closer to the mold interface cure under relatively higher thermal influence, resulting in increased surface density and mechanical resilience, as observed in skin and periosteal analogues. Collagen-derived (gelatin-based) hydrogel system is used to model a broader range of soft tissues, including dense connective tissue, adipose tissue, glandular tissue, and aerated structures such as pulmonary alveoli. The mechanical properties of the collagen-derived hydrogel are governed by the relative proportions of the solid phase (gelatin) and the liquid phase (water, glycerol, and sorbitol). Increasing plasticizer content enhances compliance and elasticity, whereas higher gelatin content yields stiffer materials. To replicate aerated tissues, an additional processing step of adding a small quantity of surfactant (e.g., one drop of Dawn dishwashing liquid) (Procter & Gamble, Cincinnati, OH) during mixing, followed by mechanical agitation using a hand or electric mixer is introduced. The process of surfactant addition incorporates air into the mixture, generating a stable foam that, upon curing, produces a porous structure with reduced density and increased compressibility, approximating the mechanical behavior of alveolar tissue.

The glutenin/gliadin hydrogel is prepared as follows. The desired quantity of glutenin/gliadin powder is measured and transferred to a mixing vessel. Gradually water is added while mixing until a cohesive, dough-like consistency is achieved and overmixing is avoided. The lipid component is incorporated and mixed until evenly distributed. The material is manually folded and stretched for 2-3 times to promote protein network formation. The material is packed into a mold that has been lightly lubricated with vegetable oil, ensuring complete filling of all features, including undercuts. In certain embodiments, glutenin/gliadin-based hydrogels benefit from release-agent application, whereas collagen-derived hydrogels may not require release treatment. In an embodiment, the ratio of glutenin/gliadin powder to liquid is 1:1 (v/v) by volume. The proportion of lipid admix is not critical. Approximately 1 mL of vegetable oil is incorporated per 60 g of glutenin/gliadin powder. (Moderate variation in lipid content does not significantly affect the properties of the hydrogel.) The filled mold is cured in a water bath maintained at 100 °C for 30-45 minutes. The curing time is adjusted based on the thickness of the construct and the thermal conductivity of the mold material. The mold is allowed to cool to a temperature that can be safely handled (40 °C), then the cured construct is demolded. For the glutenin/gliadin-based system, the interval between initial mixing and mold casting should not exceed approximately 5 minutes to prevent premature gelation and ensure proper mold filling. For the glutenin/gliadin hydrogel, preparation of mixtures exceeding approximately 250 g of powder becomes mechanically difficult to mix uniformly. To maintain homogeneity, larger volumes should therefore be prepared in smaller batches and subsequently combined if needed. Excessive mixing duration or vigorous agitation may accelerate premature polymerization in glutenin/gliadin-based hydrogels, reducing working time and increasing stiffness prior to mold placement. Extended curing duration may produce a rubber-like consistency that decreases suitability for soft-tissue simulation. In certain embodiments, molds are reusable across multiple fabrication cycles and may withstand repeated casting operations. Molds may be cleaned using warm water and mechanical brushing prior to reuse.

The collagen-derived (gelatin-based) hydrogel is prepared as follows. The required amount of gelatin powder is weighed and transferred to a microwave-safe container. Warm (non-boiling) water is gradually added while mixing to ensure complete hydration and dissolution. Glycerol and sorbitol are added in the desired proportions, mixing gently to achieve a homogeneous solution while minimizing air incorporation (unless aeration is intended). The mixture is poured into the mold promptly, prior to the onset of gelation. If viscosity increases and impedes pouring, briefly reheat (e.g., 2-3 seconds in a microwave) to restore fluidity. The filled mold is transferred to a refrigerator (~4 °C) for approximately 20 minutes or to a freezer for approximately 10 minutes to accelerate gelation. Alternatively, the material is allowed to set at room temperature for approximately 1 hour. The solidified construct is demolded. The haptic properties of the gels are judged subjectively by a panel of physicians and surgeons. For the collagen-derived (gelatin-based) hydrogel, no practical upper or lower limits are identified under typical laboratory preparation conditions. The collagen-derived hydrogel system consists of a solid phase (gelatin) and a liquid phase comprising water and variable proportions of plasticizer (glycerol) and modifier (sorbitol), which together enable tuning of mechanical properties. The overall ratio of solid to liquid phase is maintained at 1:2.25 (v/v), where the liquid phase represents the combined volume of water, glycerol, and sorbitol. As a representative formulation for a relatively stiff, elastic material approximating dense connective tissue, a composition of 1 part gelatin, 1 part glycerol, and 1.25 parts water (v/v) is used, with no sorbitol included. Incorporation of sorbitol, and adjustment of the glycerol-to-sorbitol ratio, allows systematic modulation of stiffness and elasticity, yielding materials that span a range of soft tissue analogues.

In an embodiment, the present technology uses rapid prototyping, which describes a group of processes used to fabricate a physical structure from a digital anatomically representative model generated using three-dimensional computer-aided design (CAD) data. In this embodiment, the fabricated physical structure corresponds to a surgical simulation model representing a highly realistic human body part or anatomical region. The operative fields for simulation training are fabricated using additive manufacturing technology (principally three-dimensional printing) and hydrogel molding techniques. The digital anatomically representative model may be derived from anatomically representative data and processed to generate mold geometry or structural components used to fabricate the physical simulation model. Whereas hydrogel molding is an established technique in certain medical research applications, its implementation within the present technology for medical and surgical simulation training provides anatomically representative and haptically realistic training models.

The first step to fabricate a physical simulation model is to acquire anatomically representative data corresponding to a subject anatomy in three dimensions. In certain embodiments, the anatomically representative data is stored within a computing environment and processed to generate a digital anatomically representative model corresponding to the anatomical region of interest. The digital representation of the subject patient usually is accomplished via a computed tomography (CT) scan, magnetic resonance imaging (MRI) scan, ultrasound scan, and/or a high-resolution optical scan of the surgical field obtained preoperatively. The digital data files are imported into a three-dimensional (3D) CAD application (public domain application, either 3D slicer or Blender to keep with the theme of inexpensive and accessible fabrication). Next, the CAD application converts the DICOM file obtained from the medical device to a CAD file, from which a 3D model can be created from the images to the desired output for printing the precision molds. The molds are needed to cast the previously prepared soft-tissue hydrogel simulation material. If needed, one can print simultaneously the bony components of the simulation training assembly. Next, the files are converted to an STL format that can be subsequently exported to a 3D printer (using a low-cost consumer grade printer, the prototype will print in three to six hours depending upon the complexity of the model). In the next step of the fabrication process, the prepared hydrogel components are mixed, then poured or extruded (depending on its viscosity) into the precision molds. After approximately 15-30 minutes of curing in the molds, the precision replica can be released from the mold and is ready for use in training. Completing the fabrication process will result in an anatomically and haptically accurate replica of a surgical field that can be utilized for surgical training. In an embodiment, results of data from students and teaching surgeons who rated the construct for haptic and anatomic accuracy is available if necessary to the present invention.

Augmented reality (AR) is an interactive experience in which a real-world environment is enhanced with computer-generated visual elements, sounds, and other stimuli. AR distinctly differs from Virtual Reality (VR) as AR is physical reality in which participants also see virtual elements, whereas VR represents a synthetic world in which the participant is completely immersed. Since its inception, AR has been used for a variety of purposes, most commonly gaming/entertainment/tourism, product visualization, marketing, architecture and home design, industrial maintenance, and to a limited extent, medical education. Additionally, sophisticated, expensive AR surgical navigation and/or preoperative planning systems have found their way into the operating theater whereby images of underlying anatomy are overlaid onto the operative field for accurate guidance, planning, and delivery of a surgical intervention. Although sophisticated, expensive VR simulators have been introduced for medical/surgical training, they lack the haptics required for physicians and surgeons to develop manual skills. The AR subsystem leverages the distinct training advantages of augmented reality over virtual reality by providing instructional guidance directly aligned with the physical training model. In this embodiment, AR serves to create instructional content that simulates a medical/surgical procedure while providing instruction and feedback to novice physicians training on a patient replica, (or for experienced surgeons who aim to practice a procedure on a replica of a specific patient preoperatively, or for interoperative guidance when performing surgery on a real patient). The overall aim is to enhance surgical outcomes. The instructional content takes the form of a step-by-step walk-through the medical or surgical procedure, which can be projected directly onto the patient replica in a training environment or onto the operative field in the case in which the physician is treating the actual patient. In general, AR instructional content is created by importing a 3D file representing the desired scenario usually a converted CAD file (3D engineering file). The file material is then animated, including the addition of any required surgical armamentaria and their animations, to form a sequence of steps through which the learner can cycle at their own pace. The sequence of steps is accomplished by bringing existing technologies together and by repurposing the existing technologies. For example, to coordinate position in space, the AR component system utilizes marker less technology such as sensors commonly found in an inexpensive smart phone or tablet (i.e., GPS, digital compass (magnetometer), three (3) axis gyroscope, three (3) axis accelerometer, and camera with LiDAR). Whereas none of the above technology is intended for surgical navigation or medical simulation training, the present technology found that the surgical navigation or medical simulation training technology in an inexpensive package (an Android tablet costs less than $50) is perfectly suited for the task.

In order to simulate an operative field for medical/surgical simulation training, one first needs to place the previously fabricated model of the operative field into an AR scene. Using a free AR development tool originally designed for building gaming content (e.g., Unity Game Engine personal edition), one creates a digital twin of the training model that will exist within the application, which is accomplished in the same manner as one would create a character in a gaming environment. Then, one similarly introduces further objects into the AR scene (in this instance, an operating table or chair, surgical trays with assorted armamentaria, etc.) Objects, including the AR scene, are tracked via the tracking feature in the application tool kit. Digital twins of surgical implements can be acquired and imported into the game engine library using free photogrammetry scanning software such as Qlon, Kiri Engine, or My3D scanner as these free apps are available for IOS or Android phones or tablets. After bringing the needed objects for the scenario into the AR scene, one formulates a storyboard much like how a typical game developer would use the unity engine. One lays out sequences and sub sequences in the instructional scene (e.g., positioning the patient, preoperative checklist, marking the skin, making the incisions, laying the flaps, suturing, etc.). Then, similar to the gaming environment, one arranges the content, then animates and edits as intended. The result is an instructional exercise that can be archived for distribution either on storage media or in an online depository for publication and distribution. In an embodiment, there is a growing body of scientific literature describing AI in medicine and surgery and the worldwide implementation of AI technologies in surgical residency programs as well as undergraduate medical education.

The implementations are varied but tend to focus mining data from sensors on virtual or real simulators to evaluate performance and provide feedback to learners. In the present invention, the performance observation and feedback strategies are simple, that is, the camera residing in the smartphone, tablet, or wearable display maps the novice surgeon's movements against the ideal performance. The trainee also receives step-by-step instruction via the display. Performance evaluation may be based on tracking anatomical landmarks identified from image input captured by a mobile device, wearable display, or camera-equipped interface. User hand trajectories, tool positioning, and procedural movement paths may be compared against expert-authored reference pathways to identify deviations.

In certain embodiments, reference procedural pathways representing ideal performance are generated from expert-authored training lessons encoded within an augmented reality instructional environment. A subject matter expert may define procedural steps, expected instrument trajectories, anatomical targets, movement sequencing, or positioning events corresponding to preferred procedural execution. These procedural definitions may be encoded as scripted events, object-recognition triggers, positional relationships, or movement thresholds. During operation, detected movement paths may be compared against stored reference pathways to determine similarity, deviation, timing variation, or missed procedural actions. Tracking accuracy may depend on camera resolution and positional sensing capability. In some embodiments, tracking precision may achieve submillimeter spatial resolution sufficient for procedural guidance. If the observable movement matches the ideal, then the learner receives an audible compliment as a reward. If the observable movement deviates from the expected performance, then the learner sees a flashing warning in the surgical field as well as hears an audible warning that they are about to make a misstep. Then, correctional guidance will be administered by the intelligent system. Lastly, at the successful conclusion of each sequence or subsequence, the learner receives performance feedback generally positive and complimentary in order to encourage them toward the next step (as in a gaming environment). The system design allows for real instructor feedback. That is, the learner can signal that they need the attention of a live expert, either on site or remote, to assist them. The teacher may join the learner in person or via an interactive web-based video connection. It should be noted that this multicomponent training system is not limited to surgical training. The method may be applied to varied medical training experiences, like dental procedures, anesthesia protocols, radiation therapy procedures, or even teaching medical students how to perform a physical examination. The significance of the present technology compared to existing training methods are its low cost, low complexity, low resource intensive, and easily distributable features. The key subsystem for surgical training is the new use of BCGs and rapid prototyping to replicate soft tissue in a training simulation.

Various embodiments of the present technology relate to a medical/surgical training system that provides anatomically accurate and haptically realistic simulation of medical procedures or interventions. The system integrates physical modelling, advanced soft-tissue simulation, augmented reality (AR), and artificial intelligence (AI) to enable effective skill acquisition and procedural training. Using the present technology, one can use precision medicine to train surgeons to anticipate difficult aspects of their specific patient's operation, train pre-emptively to avoid morbidity. Also, one can train physicians and other healthcare personnel in generic, (non-personalized medicine) using haptically and anatomically accurate simulators on an enterprise basis. In short, there is a critical lack of skilled medical professionals worldwide. The broad goal of the present invention is to use technology to enhance the development of medical and surgical skills, to be able to accomplish this conveniently and economically, and ultimately to make a difference in patient outcomes and accessibility of care.

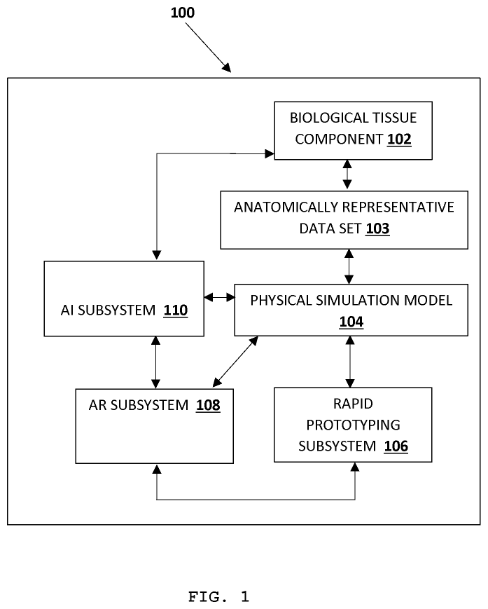

FIG. 1 illustrates a block diagram of a medical/surgical training system 100, in accordance with an embodiment. In an embodiment, the system 100 may comprise a biological tissue component 102, an anatomically representative data set 103, a physical simulation model 104, a rapid prototyping subsystem 106, an augmented reality (AR) subsystem 108, and an artificial intelligence (AI) subsystem 110.

In an embodiment, the biological tissue component 102 refers to one or more simulated anatomical tissue structures corresponding to target anatomy for procedural training. The biological tissue component 102 may represent any soft tissue, rigid tissue, or semi-rigid tissue, including vascular structures, connective tissue, muscle, fat, cartilage, bone, skin, or combinations thereof associated with an anatomical region of interest of a human or animal. By way of example, the biological tissue component 102 may correspond to anatomical structures subject to surgical intervention, including but not limited to facial features such as lips, ears, nose, or eyelids, as well as internal or external anatomical structures such as organs, vessels, joints, or composite tissue regions. In an embodiment, the biological tissue component 102 may comprise any human or animal body part, or portion thereof, that may undergo a medical or surgical procedure and is to be replicated for training, planning, or simulation purposes.

In certain embodiments, the biological tissue component 102 represents the target anatomy to be simulated, the anatomically representative data set 103 represents digital information corresponding to the target anatomy, and the physical simulation model 104 represents a fabricated physical realization of the target anatomy derived from the anatomically representative data set 103.

In an embodiment, the anatomically representative data set 103 may comprise imaging data, scan-derived information, segmented anatomical datasets, or digitally reconstructed geometry corresponding to one or more anatomical structures (the biological tissue component 102). In certain embodiments, the anatomically representative data set 103 is stored in memory and processed to generate a digital anatomically representative model representing geometry and spatial arrangement of anatomical structures (the biological tissue component 102). In certain embodiments, the anatomically representative data set 103 is derived from digital anatomical data obtained using one or more imaging modalities, including computed tomography (CT), magnetic resonance imaging (MRI), high-resolution optical scanning, ultrasound imaging, or combinations thereof. In an embodiment, the anatomically representative data set 103 may be processed to generate a digital anatomically representative model used to fabricate the physical simulation model 104. In an embodiment, the biological tissue component 102 may represent whole anatomical regions, specific organs, or localized tissue structures depending on the intended training application. In certain embodiments, the biological tissue component 102 may comprise rigid, semi-rigid, or compliant regions configured to simulate structures such as bone, cartilage, vascular frameworks, connective tissue, or soft tissue anatomy.

In an embodiment, the physical simulation model 104 may comprise a biopolymeric composite gel (BCG) formed from two or more biopolymeric materials that is configured to emulate mechanical and tactile properties of human soft tissue. In another embodiment, the physical simulation model 104 may be formed without the use of a biopolymeric composite gel, and instead may comprise one or more alternative tissue-simulating materials configured to emulate mechanical and tactile properties of human tissue. In an embodiment, the biopolymeric composite gel includes plant-derived polypeptides. In an embodiment, the polypeptides include glutenin and gliadin. In an embodiment, the gel includes an animal-derived protein. In an embodiment, the protein includes collagen or gelatin or elastin. In an embodiment, the gel further includes a plasticizer. In an embodiment, the plasticizer includes glycerol. In an embodiment, the gel further includes a polysaccharide. In an embodiment, the polysaccharide is selected from sucrose, mannose, or honey. In an embodiment, the gel is tunable to simulate skin, muscle, fat, or connective tissue. In various embodiments, the BCG is formed from a combination of biopolymeric materials, including plant-derived polypeptides, such as glutenin, gliadin, alginate or combinations thereof, animal-derived proteins, such as collagen or gelatin, plasticizers, including glycerol and polysaccharides, such as sucrose, mannose, or honey. The composition of the BCG may be varied to tune its mechanical properties, including elasticity, viscosity, tensile strength, and compressibility, which enables simulation of different tissue types, including skin, muscle, fat, and connective tissue. The BCG gel may be integrated into the physical simulation model 104 in layered or region-specific configurations to replicate heterogeneous tissue structures. In certain embodiments, the biological tissue component may form a portion of, be embedded within, or be positioned relative to the physical simulation model to simulate one or more anatomical tissue regions. In certain embodiments, the physical simulation model 104 may comprise a biopolymeric composite gel (BCG). In other embodiments, the physical simulation model 104 may comprise alternative tissue-simulating materials, including silicone-based materials, hydrogels, synthetic polymer matrices, elastomeric materials, foam structures, ballistic gels, rubber-based compounds, composite materials, or combinations thereof configured to emulate one or more mechanical or tactile properties of human tissue. In such embodiments, the physical simulation model 104 may be fabricated entirely from non-BCG materials while still achieving the desired anatomical and mechanical simulation characteristics.

Accordingly, the physical simulation model 104 may be wholly BCG-based, partially BCG-based, or entirely non-BCG-based depending on the intended training application. In certain embodiments, the physical simulation model 104 may include rigid skeletal supports, vascular conduits, nerve analogues, tubing, fluid reservoirs, or sensors integrated with soft-tissue regions to simulate additional anatomical or physiological characteristics. In embodiments where BCG materials are not used, such structural and functional components may be combined with alternative tissue-simulating materials to provide comparable realism, durability, and performance for medical/surgical training and procedural rehearsal.

The physical simulation model 104 may be patient-specific or generic, planar or three-dimensional, and single-layer or multi-layer depending on the desired training application. The physical simulation model 104 provides a tangible, manipulable representation of anatomy corresponding to the biological tissue component 102.

The rapid prototyping subsystem 106 is configured to fabricate at least a portion of the physical simulation model 104 based on a digital anatomically representative model generated from the anatomically representative data set 103. The rapid prototyping subsystem 106 may fabricate one or more molds, structural components, or scaffolds used to form the physical simulation model 104. In certain embodiments, the rapid prototyping subsystem 106 may fabricate rigid skeletal structures, cartilage analogues, or support frameworks integrated with soft-tissue regions of the physical simulation model 104.

In an embodiment, the rapid prototyping subsystem 106 includes three-dimensional printing. Printing techniques may include fused deposition modelling (FDM), stereolithography (SLA), selective laser sintering (SLS), or other additive manufacturing processes. The anatomically representative data set 103 may be processed to generate printable geometries that enable patient-specific or generalized anatomical replication. The rapid prototyping subsystem 106 allows efficient fabrication of training models with high geometric fidelity.

The augmented reality (AR) subsystem 108 is configured to overlay instructional content onto the physical model 104 in real time. In one embodiment, the AR subsystem 108 operates via a mobile device, tablet, or wearable display. The AR subsystem 108 may utilize marker-based or marker less tracking to align digital content with the physical model 104. In an embodiment, the AR subsystem 108 provides step-by-step procedural guidance. In an embodiment, the procedural guidance includes visual overlays aligned with anatomical structures. In an embodiment, instructional content includes animations, annotations, or visual cues. Instructional content may include step-by-step procedural guidance, visual overlays corresponding to anatomical structures, annotations and labels and animated demonstrations of procedural steps. The AR subsystem 108 enhances user interaction by providing contextual and spatially aligned guidance during training.

The artificial intelligence (AI) subsystem 110 is configured to evaluate user performance and provide feedback. The artificial intelligence subsystem 110 also monitors and evaluates user interaction with the training system. In an embodiment, the AI subsystem 110 analysis motion of a user relative to an expected procedural pathway. In one embodiment, the AI subsystem 110 tracks user motion relative to a predefined procedural pathway. The AI subsystem 110 may analyze parameters such as tool positioning, movement trajectories, timing, adherence to procedural steps, force application, and interaction relative to anatomical landmarks. In certain embodiments, the AI subsystem 110 generates feedback by comparing observed user interaction data against stored procedural criteria, expected motion pathways, procedural thresholds, or predefined training metrics. Feedback may be generated when deviations from an expected procedural pathway are detected, when procedural milestones are completed, or when evaluation criteria are satisfied. Based on the analysis, the system 100 provides feedback, which may include visual cues or alerts, auditory guidance, haptic signals and quantitative performance scoring. In an embodiment, feedback includes visual, auditory, or haptic signals. Feedback generated by the AI subsystem 110 may be delivered through one or more output modalities. In certain embodiments, feedback is provided as visual feedback, including highlighted anatomical regions, graphical indicators, instructional overlays, warning symbols, procedural prompts, text notifications, or performance dashboards displayed by the augmented reality subsystem 108. In certain embodiments, feedback is provided as auditory feedback, including spoken instructions, alerts, tonal cues, verbal guidance, or recorded instructional prompts. In certain embodiments, feedback is provided as haptic feedback, including vibration, resistance, force cues, tactile stimulation, or localized pressure generated through an instrument, wearable device, handheld controller, or interaction interface. In certain embodiments, feedback may be delivered in response to sensor-derived interaction data captured by cameras, motion sensors, force sensors, pressure sensors, inertial measurement units, optical tracking systems, proximity sensors, or combinations thereof. Feedback may be delivered in real time during procedural interaction or after completion of a training session. In an embodiment, the AI subsystem 110 provides performance scoring.

The feedback generated by the AI subsystem 110 may include one or more of: (i) corrective feedback identifying a deviation between an observed user motion or tool position and a stored ideal procedural pathway and indicating a direction, magnitude, or step at which the deviation occurred; (ii) reinforcing feedback indicating that an observed user motion conforms to the stored ideal procedural pathway, optionally accompanied by an audible notification or visual indicator; (iii) warning feedback delivered when the AI subsystem 110 predicts that a user motion may result in a procedural error or unsafe action, the warning feedback including a visual cue, auditory alert, or haptic alert; (iv) summative feedback delivered at completion of a procedural step, sub-procedure, or full procedure, including a quantitative performance score or comparison to stored benchmark criteria; (v) instructional feedback that modifies instructional content displayed by the augmented reality subsystem 108; and (vi) on-demand feedback generated in response to a user query based on a current procedural state and stored procedural criteria. In an embodiment, the AI subsystem 110 enables remote expert as an integrated feature of the training system, allowing instructors to review performance and provide guidance in real time or asynchronously. The system 100 enables anatomically and haptically realistic simulation of a medical or surgical procedure. The medical or surgical procedure components operate in conjunction to simulate real-world medical or surgical environments.

In use, a user is provided with a physical simulation model 104 incorporating the biopolymeric composite gel. The AR subsystem 108 displays instructional content aligned with the physical simulation model 104, guiding the user through a medical or surgical procedure. The user interacts with the physical simulation model 104 using appropriate instruments or techniques. The AI subsystem 110 tracks and analysis the interaction, generating feedback based on comparison to stored procedural criteria and providing real-time or delayed feedback to improve performance.

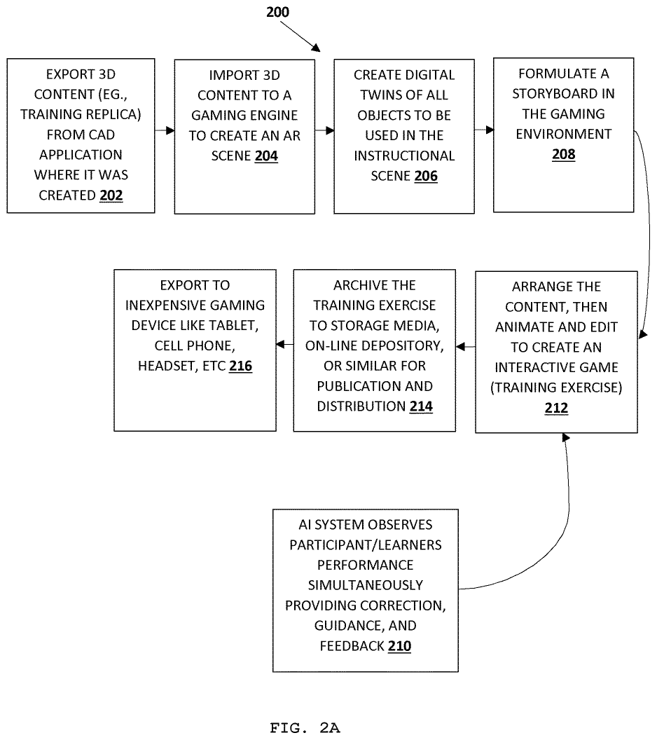

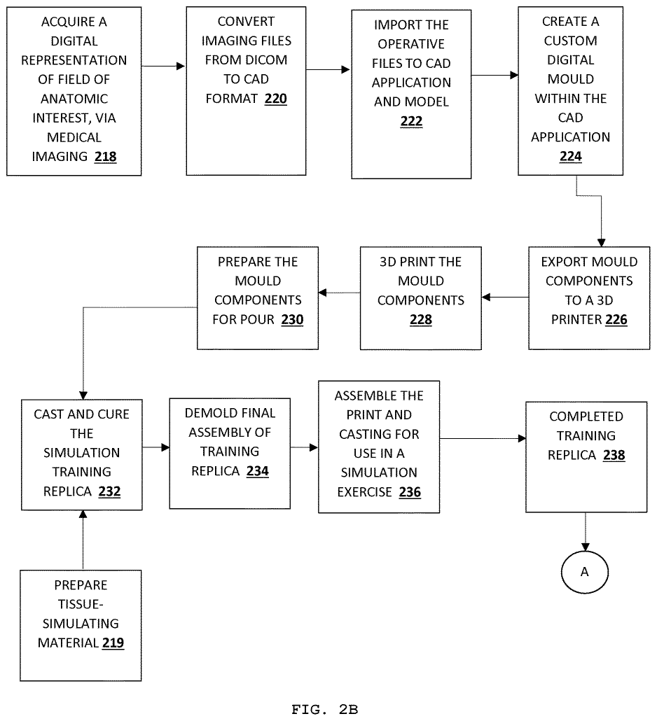

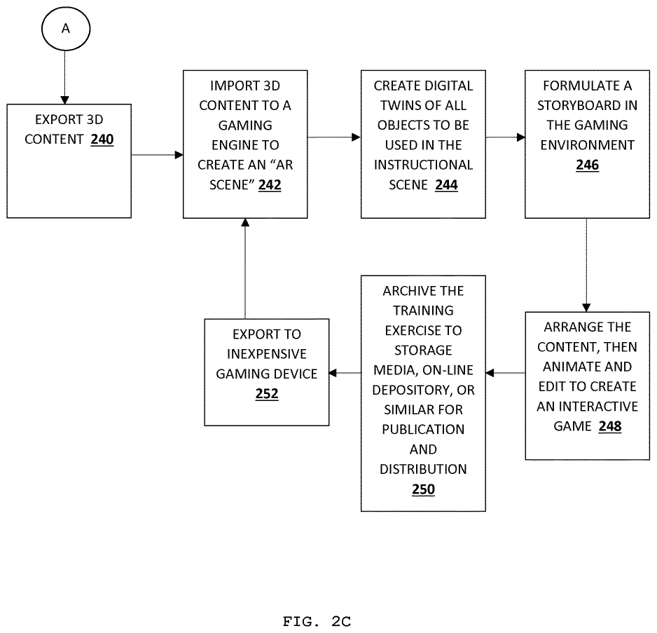

FIG. 2A illustrates a process flowchart 200 of AR/AI creation of instructional content for simulation training, in accordance with an embodiment. At step 202, three-dimensional (3D) content (eg., training replica) is exported from CAD application where it was created. At step 204, three-dimensional (3D) content is imported to a gaming engine to create an AR scene. At step 206, digital twins of all objects to be used in the instructional scene are created. At step 208, a storyboard is formulated in the gaming environment. At step 210, the training application is scripted to define observation logic, performance evaluation criteria, corrective prompts, and feedback responses that will be applied during learner interaction. The AI subsystem may establish expected procedural pathways, scoring criteria, motion analysis parameters, or feedback triggers used during subsequent interaction with the training system. At step 212, the content is arranged, then animated and edited to create an interactive game (training exercise). At step 214, the training exercise is archived to storage media, on-line depository, or similar for publication and distribution. At step 216, the training exercise in the storage media, on-line depository, or similar for publication and distribution is exported to inexpensive gaming device like tablet, cell phone, headset, etc.

FIG. 2B illustrates a process of fabrication of physical/anatomic replicas for simulation training, in accordance with an embodiment. Rapid prototyping describes a group of processes used to quickly fabricate a model of a physical part or assembly using three-dimensional computer-aided design (CAD) data. In this embodiment, the “physical part” and “assembly” is a highly-realistic human body part. One fabricates the operative fields for surgical simulation training using “additive manufacturing” technology (principally 3D printing) and “hydrogel molding” techniques. Whereas hydrogel molding is an established technique in some areas of medical research our implementation of its use for medical/surgical training is unique. The fabrication workflow may begin with acquisition of anatomically representative data corresponding to a subject anatomy using one or more imaging modalities. The acquired imaging data may include computed tomography (CT), magnetic resonance imaging (MRI), ultrasound imaging, optical scanning, or combinations thereof. The imaging data may be processed to generate a digital anatomical dataset corresponding to the anatomical region of interest. The digital anatomical dataset may then be converted into a digital anatomically representative model within a computer-aided design (CAD) environment. The digital anatomically representative model may be further processed to generate mold geometry or printable structural components. The mold geometry may be exported to a rapid prototyping system to fabricate one or more molds or structural components, which are subsequently used to produce a physical simulation model.

The first step to fabricate a precision surgical simulation replica, is to acquire a digital representation of the subject patient's anatomy in three dimensions. At step 218, a digital representation of field of anatomic interest is acquired via medical imaging. This usually is accomplished via a CT scan, MRI scan, ultrasound scan, and/or a high-resolution optical scan of the surgical field obtained preoperatively. At step 219, the components of composite biopolymeric hydrogel are mixed. At step 220, the imaging files are converted from DICOM to CAD format. The digital data files are imported into a 3D CAD application. In some embodiments, a free public domain application is used (either 3D-Slicer (Kikinis et al., 2014) or Blender (Blender Online Community, n.d.)) to keep with the theme of inexpensive and accessible fabrication. The CAD application converts the DICOM file obtained from the medical device to a CAD file from which we can 3D model the images to the desired output for printing the precision molds that are needed to cast the previously-prepared soft-tissue hydrogel simulation material. If needed, one can print the bony components of the simulation training assembly. At step 222, the operative field (anatomic area of interest) is imported to the CAD application for modeling. The files are converted to an STL format that can be subsequently exported to a 3-D printer (Using a low-cost consumer-grade printer, the prototype will print in three to six hours, depending upon the complexity of the model). In certain embodiments, printing is performed at a high available print resolution with substantially full infill density to improve anatomical fidelity, heat transfer consistency, and mold durability. In the next step of the fabrication process, the prepared hydrogel components are mixed, then poured or extruded (depending on their viscosity) into the precision molds. At step 224, a custom digital mold is created within the CAD application. At step 226, mold components are exported to a 3D printer. At step 228, the mold components are 3D printed. At step 230, the mold components are prepared for pouring. At step 232, the simulation training replica is cast and cured. At step 234, the final assembly of training replica is demolded. At step 236, multiple model components are assembled to form a completed simulation replica. Assembly may include integration of hydrogel components, rigid printed structures, vascular simulators, nerve analogues, tubing, or other embedded anatomical features. In certain embodiments, tissue layers are fabricated separately and subsequently assembled to permit placement of intermediate structures between layers. At step 238, the training replica is completed. After approximately 15-30 minutes of curing in the molds, the precision surgical replica can be “released” from the mold and is ready for use in surgical training. The result is an anatomically and haptically accurate replica of a surgical field that can be utilized for training. Mold materials may be selected according to thermal resistance, durability, and reusability. Polylactic acid (PLA) may be used for lower-temperature hydrogel systems, while acrylonitrile butadiene styrene (ABS) or heat-stable resins may be used for molds exposed to elevated curing temperatures. The training replica generated in the process of FIG. 2B is used in the process of creation of instructional content for simulation training described along with FIG. 2C.

In certain embodiments, layered simulation models are assembled from independently fabricated tissue regions. Individual hydrogel layers may represent distinct anatomical structures, including muscle, fascia, glandular tissue, adipose tissue, or skin. Intermediate anatomical components, including vascular conduits, nerve simulators, or support structures, may be positioned between layers during assembly. In some embodiments, compartmentalized molds permit simultaneous casting of multiple tissue regions having distinct mechanical properties

FIG. 2C illustrates a process of creation of instructional content for simulation training, in accordance with an embodiment. At step 240, the 3D content is exported from the training replica generated in step 238 in the process flow of FIG. 2B. At step 242, the 3D content is imported to a gaming engine to create an “AR scene”. At step 244, the digital twins of all the objects are created to be used in the instructional scene. At step 246 a storyboard is formulated in the gaming environment. At step 248, the content is arranged and then animated and edited to create an interactive game. At step 250, the training exercise is archived to storage media, on line depository or similar for publication and distribution. At step 252, the training exercise is exported to inexpensive gaming device such as, tablet, cell phone, headset, etc.

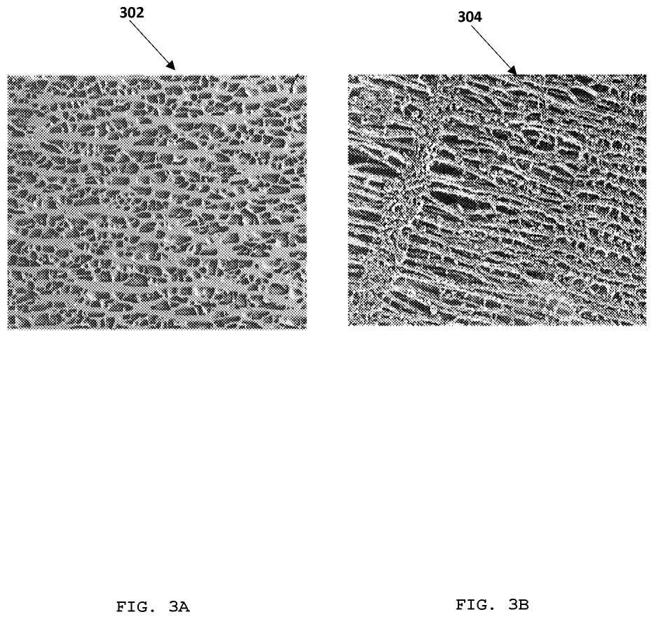

FIG. 3A illustrates a scanning electron micrograph 302 of gliadin/glutenin composite polymeric hydrogel, in accordance with an embodiment.

FIG. 3B illustrates a scanning electron micrograph 304 of actin/myosin/titin in a human muscle fiber, in accordance with an embodiment. FIG. 3A-3B shows the comparison of the microscopic structure of gliadin/glutenin composite polymeric hydrogel 302 to the microscopic structure of actin/myosin/titin 304 in a polymeric hydrogel. The comparison shows the high structural similarity between the present invention and naturally occurring human flesh, thus accounting for similar haptic properties.

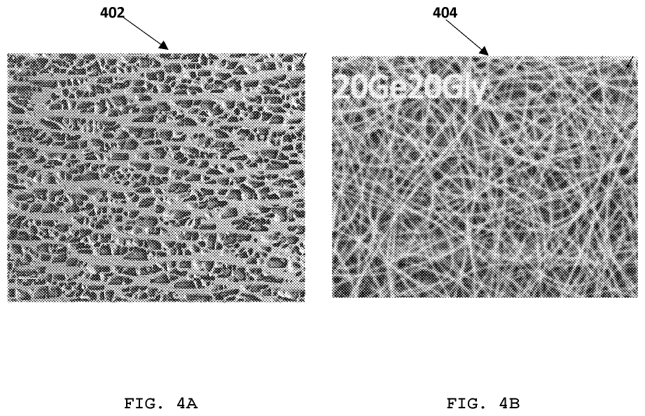

FIG. 4A illustrates a scanning electron micrograph 402 of gliadin/glutenin composite polymeric hydrogel, in accordance with an embodiment.

FIG. 4B illustrates a scanning electron micrograph 404 of collagen/glycerol composite polymeric hydrogel, in accordance with an embodiment. FIG. 4A-4B shows the comparison of the microscopic structure of gliadin/glutenin composite polymeric hydrogel 402 to collagen/glycerol composite polymeric hydrogel 404. By exchanging components of the composite gels, the microstructure changes from a linear array of crosslinked fibers (gliadin/glutenin composite polymeric hydrogel 402) to an amorphous, loose array (collagen/glycerol composite polymeric hydrogel 404) to simulate the haptics of loose areolar tissue. In a further embodiment, one can reduce the hydration of the collagen/glycerol composite polymeric hydrogel 404 while increasing the glycerol content to accurately simulate the haptics of dense connective tissue.

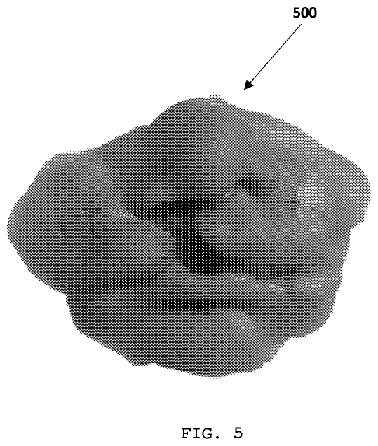

FIG. 5 illustrates a preoperative simulation model of 19-week-old infant 500, in accordance with an embodiment. The anatomically and haptically accurate replica as shown in FIG. 5 can be used to rehearse preoperatively a cleft lip reconstruction and thus mitigate the risk during the actual patient interaction. For instance: A novice surgeon needs to surgically repair a cleft lip in a 19-week-old infant. Having never done this complex procedure before, they require instruction. Traditional instruction would involve a structured practice session at a lab bench operating on the lips of a slaughtered pig using a printed manual while under the eyes of an experienced teaching surgeon. The traditional method does not work particularly well and is expensive in terms of time and resources. However, using an anatomically and haptically accurate replica fabricated via components 1 and 2 of the present invention, the novice surgeon can rehearse the prospective surgery anywhere, at any time, obviating the need for a structured scheduled learning session. Also, the learner can now use any device equipped with a camera (smartphone, tablet, smart glasses) to see three-dimensional (3D) animations telling them exactly what they need to do, where and how they need to do it. Moreover, the expertise of the medical center most experienced staff can be built into the application thus providing instantaneous feedback if the learner commits a misstep. Each step can contain text instructions, narration, diagrams photographs or videos for reference, as well as the three-dimensional (3D) animated content. Items can be made to fade in or out or flash different colors and additional effects can be added to help draw the user's attention to areas of interest or concern. The learner has the option to ask the built-in AI expert when they do not understand an instruction.

In an embodiment, a soft-tissue simulation material (such as material used to prepare simulation model shown in FIG. 5) is provided. The soft-tissue simulation material includes a biopolymeric composite hydrogel formed from a plurality of biopolymers, where the hydrogel is engineered to replicate one or more mechanical properties of human tissue selected from elasticity, compressibility, density, and tensile strength. In an embodiment, the biopolymeric composite gel includes plant-derived polypeptides. In an embodiment, the polypeptides include glutenin and gliadin. In an embodiment, the gel includes an animal-derived protein. In an embodiment, the protein includes collagen or gelatin. In an embodiment, the gel further includes a plasticizer. In an embodiment, the plasticizer includes glycerol. In an embodiment, the gel further includes a polysaccharide. In an embodiment, the polysaccharide is selected from sucrose, mannose, or honey. In an embodiment, the gel is tunable to simulate skin, muscle, fat, or connective tissue.

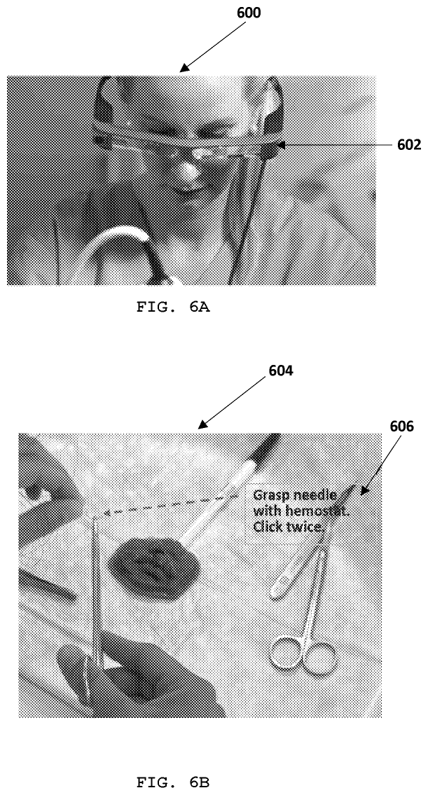

FIG. 6A-6B illustrates a trainee participating in a self-directed simulation tutorial using AR/AI with navigation, annotation, animation, real-time guidance and feedback 600/604, in accordance with an embodiment. The user interface in this embodiment is android-powered smart glasses although other interfaces are possible such as mobile phone or tablets. FIGS. 6A, 600 shows a camera residing in the wearable display 602, which maps the novice surgeon's movements against the ideal performance. The trainee also receives step-by-step instruction via the display 606 as shown in FIGS. 6B, 604. In the FIGS. 6B, 604 the display 606 shows instructions as grasp needle with hemostat, click twice. If the observable movement matches the ideal, then the learner receives an audible compliment as a reward. If the observable movement deviates from the expected performance, then the learner sees a flashing warning in the surgical field as well as hears an audible warning that they are about to make a misstep. Then, correctional guidance will be administered by the intelligent system. Lastly, at the successful conclusion of each sequence or subsequence, the learner receives performance feedback generally positive and complimentary in order to encourage the learner toward the next step (as in a gaming environment).

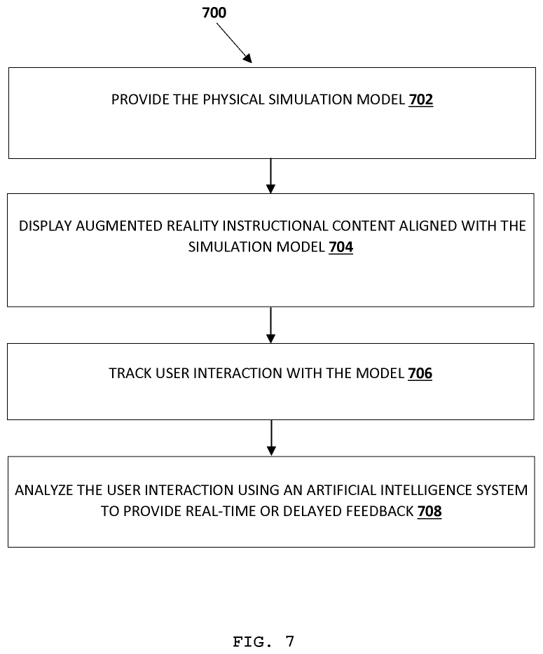

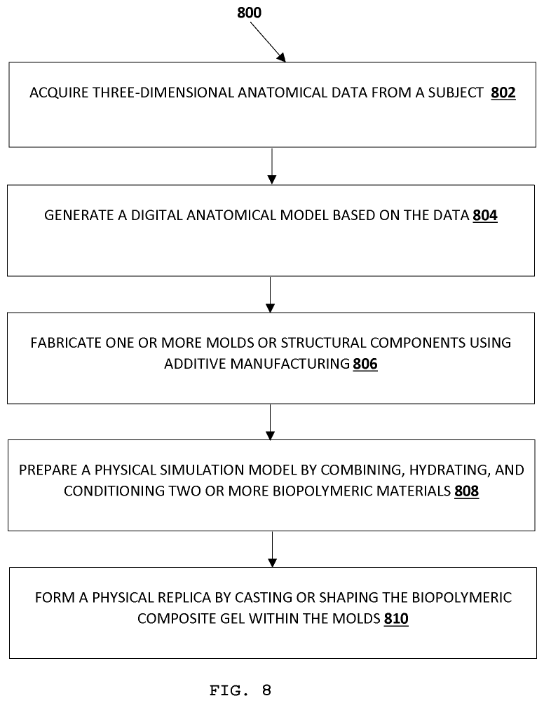

FIG. 7 illustrates a flowchart 700 of a method for training a user in a medical or surgical procedure using a physical simulation model, in accordance with an embodiment. At step 702, the physical simulation model including provided for use during procedural training. In certain embodiments, the physical simulation model 104 may comprise a tissue-simulating model configured to emulate one or more anatomical tissues or structures. The physical simulation model 104 may comprise a biopolymeric composite gel (BCG), alternative tissue-simulating materials, or combinations thereof.

At step 704, augmented reality instructional content aligned with the simulation model is displayed. The augmented reality instructional content may include procedural guidance, anatomical overlays, tool placement indicators, step-by-step instructions, directional prompts, safety boundaries, anatomical labels, reference imagery, or animated procedural demonstrations spatially registered relative to the physical simulation model. In certain embodiments, the augmented reality instructional content is dynamically updated according to a current procedural stage or detected user interaction

At step 706, user interaction with the model is tracked. User interaction may include monitoring hand motion, tool positioning, movement trajectories, orientation, contact events, force application, timing, procedural sequencing, or interaction relative to anatomical landmarks of the physical simulation model. Tracking may be performed using cameras, motion sensors, optical tracking systems, inertial sensors, depth sensors, or combinations thereof.

At step 708, the user interaction is analyzed using an artificial intelligence system to provide real-time or delayed feedback, where the method improves procedural skill acquisition. The artificial intelligence system may compare observed user interaction against stored procedural criteria, expected motion pathways, predefined procedural thresholds, or benchmark performance data. Feedback may include corrective guidance, warnings, procedural scoring, instructional prompts, progression cues, error detection, visual indicators, auditory alerts, haptic feedback, or combinations thereof. In certain embodiments, the feedback is generated when deviations from an expected procedural pathway are detected or when procedural milestones are completed.

In an embodiment, training is performed asynchronously without a live instructor. In such embodiments, instructional content and performance evaluation may be automatically delivered through the augmented reality subsystem and artificial intelligence subsystem without real-time supervision. In an embodiment, training includes surgical, dental, anesthesia, diagnostic, interventional, or therapeutic procedures. In an embodiment, the method further includes storing instructional modules in a digital library. The digital library may include procedure-specific guidance, anatomical models, evaluation criteria, recorded training sessions, benchmark performance profiles, or instructional workflows accessible for repeated training sessions. In an embodiment, the system operates in a low-resource environment. Such environments may include remote healthcare settings, educational facilities, mobile training units, field hospitals, or locations with limited access to expert instructors or specialized equipment. In an embodiment, the system is used for continuing medical education, procedural rehearsal, competency assessment, certification preparation, or skills maintenance across multiple training sessions.

FIG. 8 illustrates a flowchart 800 of a method of producing a medical or surgical simulation model, in accordance with an embodiment. At step 802, three-dimensional anatomical data is acquired from a subject. In an embodiment, the anatomical data is obtained from CT, MRI, ultrasound, or optical scanning. At step 804, a digital anatomical model is generated based on the data. At step 806, one or more molds or structural components are fabricated using additive manufacturing. In an embodiment, fabrication is completed within 6 hours. At step 808, a tissue-simulating material (the physical simulation model) is prepared by combining, and hydrating two or more biopolymeric materials. In certain embodiments, the tissue-simulating material may comprise a biopolymeric composite gel, hydrogel, silicone-based material, elastomeric material, synthetic polymer matrix, or any combinations thereof. In an embodiment, the physical simulation model may be made without the use of a biopolymeric composite gel. In an embodiment, gel curing occurs within 30 minutes. At step 810, a physical replica is formed by casting or shaping the biopolymeric composite gel within the molds. In another embodiment, the physical replica may be formed by casting or shaping one or more non-biopolymeric materials, including silicone-based materials, elastomeric materials, or synthetic polymer matrices, without the use of a biopolymeric composite gel. The replica exhibits anatomical geometry and mechanical properties representative of human tissue. In an embodiment, the model is generated using computer-aided design software. In some embodiments, the material can be rolled into layers of selective thickness rather than casting the dough-like glutenin/gliadin preparation. The sheets are cured in a water bath (in plastic wrap to limit additional water absorption). Following curing, the sheets are cut into defined shapes of muscle or skin. An anatomic replica is assembled manually with the layers glued together with powdered transglutaminase (meat glue). This technique is particularly useful when one needs to simulate the acoustic properties of soft tissues when training for ultrasonic guided surgical or medical procedures. During manual assembling of anatomic replicas, layers of different compositions or combinations of different composite hydrogels can be utilized.

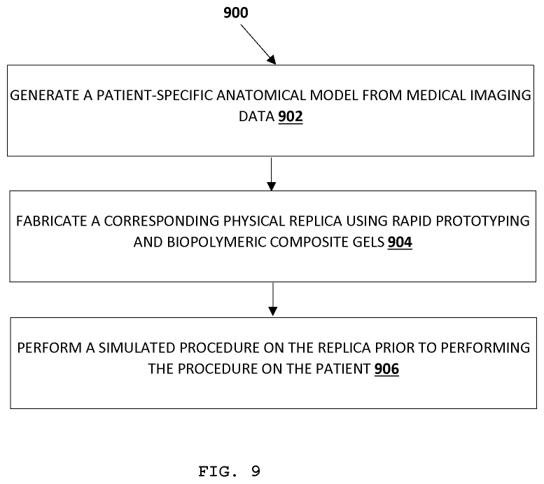

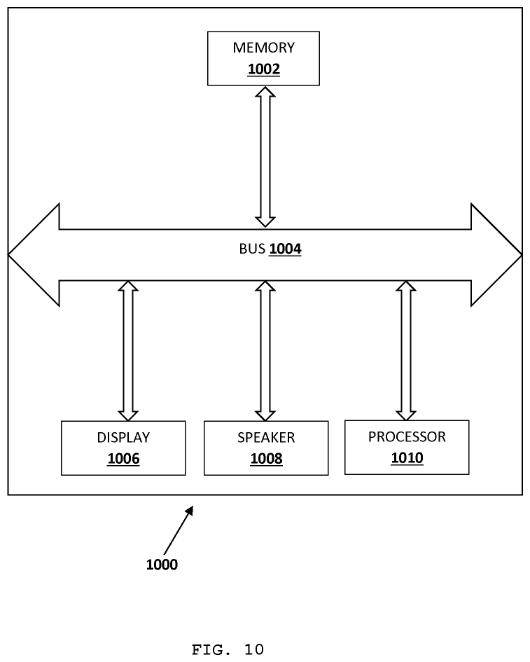

FIG. 9 illustrates a flowchart 900 of a method for patient-specific procedural rehearsal, in accordance with an embodiment. At step 902, a patient-specific anatomical model is generated from medical imaging data. At step 904, a corresponding physical replica is fabricated using rapid prototyping and biopolymeric composite gels. At step 906, a simulated procedure is performed on the replica prior to performing the procedure on the patient. In an embodiment, the gels are matched to specific anatomy via the mold preparation steps. The configuration of the mold is derived from the medical imaging data obtained from a specific patient, including high-resolution optical scanning, CT, MRI, ultrasonography, or combinations thereof. In another embodiment, the corresponding physical replica may be fabricated without the use of biopolymeric composite gels. For example, the physical replica may be formed from one or more tissue-simulating materials, including hydrogels, silicone-based materials, elastomeric materials, synthetic polymer matrices, or combinations thereof. In such embodiments, the patient-specific anatomical model may still be generated from the medical imaging data, the mold or structural configuration may still be derived from the patient-specific anatomy, and the simulated procedure may still be performed on the resulting physical replica prior to performing the procedure on the patient.

In an embodiment, a kit for producing a medical or surgical simulation model is provided. The kit includes one or more biopolymeric gel precursor materials, instructions for preparing a composite hydrogel and a physical mold, or a digital file configured for fabrication of an anatomically representative structure. In an embodiment, materials are pre-measured. The kit enables fabrication of a training model at a point of use. In an embodiment, the digital file is patient specific. In an embodiment, the kit is configured for field deployment. In an embodiment, the kit further includes access to AR/AI instructional content. In another embodiment, the kit may be configured to produce a physical simulation model without the use of biopolymeric composite gels. For example, the kit may include one or more alternative tissue-simulating materials, including hydrogels, silicone-based materials, elastomeric materials, synthetic polymer matrices, or combinations thereof, along with corresponding preparation instructions. In such embodiments, the physical simulation model may be fabricated using the provided mold or digital file in a manner consistent with the disclosed methods, without reliance on biopolymeric composite gel materials.

FIG. 10 illustrates a block diagram of a computing device 1000 configured to perform any one or more of the methodologies herein, in accordance with an embodiment. The computing device has a memory 1002 storing a set of computer instructions, a bus 1004, a video display unit 1006, an audio output unit 1008, and a processor 1010 capable of processing a set of instructions to perform any one or more of the methodologies herein, according to an embodiment herein. The processor 1010 may enable digital content to be consumed in the form of video for output via the video display unit 1006 or audio for output via the audio output unit 1008. An example of the audio output unit 1008 may include a speaker. An example of the input unit may include, but is not limited to a microphone, a keyboard, a haptic input device, a camera, and the like. The processor 1010 may also carry out the methods described herein and in accordance with the embodiments herein.

Digital content may also be stored in the memory 1002 for future processing or consumption. The memory 1002 may also store program-specific information and/or service information (PSI/SI), including information about digital content (e.g., the detected information bits) available in the future or stored from the past. A user may view the stored information on the display 1006 and select an item for viewing, listening, or other uses via input, which may take the form of keypad, scroll, or other input device(s) or combinations thereof. When digital content is selected, the processor 1010 may pass information. The content and PSI/SI may be passed among functions within the user devices using the bus 1004.

The glutenin/gliadin hydrogel, a native construct has a limited shelf-life. The glutenin/gliadin hydrogel BCG is intended for immediate use as they maintain most accurate properties for 48 hours at room temperature. The glutenin/gliadin hydrogel is refrigerated in a plastic wrapper and can be stored for a week. When warmed to room temperature, the glutenin/gliadin hydrogel regain their original properties. Thereafter, there is mold growth and dehydration of the specimens. When treated with 0.3% calcium propionate, and refrigerated, the shelf-life is 60 to 90 days. The collagen-derived (gelatin-based) hydrogel construct is highly stable. In certain formulations, refrigerated collagen-derived hydrogels may remain usable for extended periods, including periods approaching one year, depending on storage conditions and preservative content. Moreover, the material can be reused after one year storage by placing in a microwave oven and gently warming until it regains fluidity for a new casting.

In certain embodiments, collagen-derived hydrogels may be pre-portioned into smaller storage units, such as cube-shaped portions, and refrigerated for extended durations exceeding twelve months. The hydrogel may be reheated and recast multiple times without substantial degradation of tactile or mechanical performance under typical storage and handling conditions.

Various embodiments of the present technology are used for training in a variety of medical disciplines, including but not limited to medical/surgical procedures, dental procedures, anesthesia techniques and diagnostic interventions. The present technology is suitable for use in educational institutions, hospitals, simulation centers, and low-resource environments. The present technology uses biopolymeric composite gels (BCGs) which enables accurate replication of the mechanical and tactile properties of human soft tissues, improving procedural realism compared to conventional synthetic materials. An integration with rapid prototyping technologies allows fabrication of anatomically precise models, closely replicating real human structures and spatial relationships. The system can be generated from patient-specific digital anatomical data, enabling preoperative rehearsal and personalized procedural planning, thereby reducing intraoperative risk. The combination of physical simulation, augmented reality guidance, and artificial intelligence-driven feedback accelerates learning and improves procedural competency. The present technology eliminates the need for live patient training, reduces reliance on cadavers and animal models, and addresses ethical concerns associated with traditional training methods. The present technology offers a more affordable and scalable solution suitable for widespread adoption, including in low-resource settings, compared to cadaveric and high-end virtual reality systems. The AI subsystem provides objective performance evaluation, including motion tracking, scoring, and corrective guidance, enabling continuous improvement without constant expert supervision. The augmented reality subsystem enhances user engagement by overlaying real-time instructional content directly onto the physical model. The system can be adapted for various applications, including medical/surgical, dental, anesthesia, and diagnostic training. The present technology components can be reused or replaced independently, reducing long-term operational costs and allowing flexible training configurations. The present technology supports remote expert interaction and asynchronous learning, enabling training across geographically distributed users. The properties of the BCG can be adjusted to simulate different tissue types such as skin, muscle, fat, and connective tissue, increasing the breadth of training scenarios.

In certain embodiments, a computing device may be configured to support operation of the disclosed medical or surgical training system by executing instructions associated with augmented reality rendering, anatomical model processing, user interaction tracking, and artificial intelligence-based feedback generation. The computing device may include one or more processors, memory, communication interfaces, sensors, and display components configured to receive anatomical data, process instructional content, monitor procedural interaction, and provide visual, auditory, or haptic feedback during a training session. Such computing functionality may be implemented using a mobile device, tablet, wearable display, workstation, or network-connected computing platform to facilitate operation of the disclosed system.

What is claimed is:

1. A physical simulation model, comprising:
a. a biopolymeric composite hydrogel formed from a plurality of biopolymers, wherein the hydrogel is formulated to provide a selected elasticity, compressibility, density, or tensile response corresponding to a target tissue characteristic.

2. The physical simulation model of claim 1, wherein the biopolymeric composite gel comprises plant-derived polypeptides.

3. The physical simulation model of claim 1, wherein the polypeptides include glutenin and gliadin.

4. The physical simulation model of claim 1, wherein the gel comprises an animal-derived protein.

5. The physical simulation model of claim 4, wherein the animal-derived protein comprises collagen or gelatin.

6. The physical simulation model of claim 2, wherein the gel further comprises a plasticizer.

7. The physical simulation model of claim 6, wherein the plasticizer comprises glycerol.

8. The physical simulation model of claim 2, wherein the gel further comprises a polysaccharide.

9. The physical simulation model of claim 4, wherein the animal-derived protein is gelatin and the gel further comprises sorbitol and glycerol in a mass ratio configured such that the gel undergoes a sol-gel transition at a temperature between 30 °C and 60 °C and recovers its mechanical properties after at least three thaw-remold cycles.

10. A method of producing a medical/surgical simulation model, the method comprising:
a. acquiring three-dimensional anatomical data from a subject;
b. generating a digital anatomical model based on the data;
c. fabricating one or more molds or structural components using additive manufacturing;
d. preparing a biopolymeric composite gel by combining, hydrating, and conditioning two or more biopolymeric materials; and
e. forming a medical/surgical simulation model corresponding to the digital anatomical model by casting or shaping the biopolymeric composite gel within the one or more molds.

11. A method for training a user in a medical/surgical procedure, the method comprising:
a. providing the user a physical simulation model;
b. displaying to the user, via an augmented reality device, instructional content that is spatially aligned with the physical simulation model;
c. tracking the user, via one or more sensors, user interaction with the physical simulation model; and
d. analyzing the user interaction using an artificial intelligence system to provide real-time or delayed feedback based on comparison to stored procedural guidance data;
e. modifying the displayed instructional content based on generated feedback.

12. A medical/surgical training system, comprising:
a. a biological tissue component;
b. an anatomically representative data set stored in memory and configured to generate a digital anatomically representative model;
c. a physical simulation model;
d. a rapid prototyping subsystem configured to fabricate at least a portion of the physical simulation model based on the digital anatomically representative model generated from the anatomically representative data;
e. an augmented reality (AR) subsystem configured to align digital instructional content relative to a spatial position of the surgical simulation model; and
f. an artificial intelligence (AI) subsystem configured to receive interaction data associated with a user interacting with the physical simulation model and generate procedural feedback based on comparison to stored procedural criteria.

13. The medical/surgical training system of claim 12, wherein a physical simulation model comprises a biopolymeric composite gel (BCG) formed from two or more biopolymeric materials configured to emulate a mechanical property of human soft tissue selected from the group consisting of elasticity, compressibility, density, and tensile strength.

14. The medical/surgical training system of claim 13, wherein the biopolymeric composite gel comprises plant-derived polypeptides.

15. The medical/surgical training system of claim 14, wherein the polypeptides include glutenin and gliadin.

16. The medical/surgical training system of claim 13, wherein the gel comprises an animal-derived protein.

17. The medical/surgical training system of claim 16, wherein the protein comprises collagen or gelatin.

18. The medical/surgical training system of claim 13, wherein the gel further comprises a plasticizer.

19. The medical/surgical training system of claim 18, wherein the plasticizer comprises glycerol.

20. The medical/surgical training system of claim 13, wherein the gel further comprises a polysaccharide.
